(19) United States
(12) Patent Application Publication
(10) Pub. No.: US 2014/0174532 A1
(43) Pub. Date: Jun. 26, 2014

(54) OPTIMIZED ANTI-REFLECTION COATING LAYER FOR CRYSTALLINE SILICON SOLAR CELLS

(71) Applicants: Michael P. Stewart, San Francisco, CA (US); Damanjot Kaur Kochhar, San Jose, CA (US)

(72) Inventors: Michael P. Stewart, San Francisco, CA (US); Damanjot Kaur Kochhar, San Jose, CA (US)

(21) Appl. No.: 13/724,083

(22) Filed: Dec. 21, 2012

(51) Int. Cl. H01L 31/052; H01L 31/18

(52) U.S. Cl. CPC H01L 31/0522; H01L 31/18
USPC 136/259; 438/72

(57) ABSTRACT

Embodiments of the invention include a solar cell and methods of forming a solar cell. Specifically, the methods may be used to form a passivation/anti-reflection layer having desired functional and optical properties on a solar cell substrate. In one embodiment, a method of forming an anti-reflection layer on a solar cell substrate, the method includes flowing a first processing gas mixture into a processing chamber, wherein the first processing gas mixture includes at least a silicon containing gas and a nitrogen containing gas, wherein a ratio by flow volume of the silicon containing gas to the nitrogen containing gas supplied to the first processing gas mixture is controlled at between about 2:1 to about 1:5, applying a source RF power to the processing chamber in the presence of the first processing gas mixture, controlling the process pressure under 100 mTorr, and forming a silicon nitride containing layer on the substrate.

### BACKGROUND OF THE INVENTION

1. Field of the Invention

Embodiments of the present invention generally relate to the fabrication of solar cells and particularly to an anti-reflective coating (ARC) layer of silicon crystalline solar cells.

2. Description of the Related Art

Solar cells are photovoltaic devices that convert sunlight directly into electrical power. The most common solar cell material is silicon (Si), which may be in the form of single, polycrystalline, multi-crystalline substrates, or amorphous films. Efforts to reduce the cost of manufacturing solar cells, and thus the cost of the resulting cell, while maintaining or increasing the overall efficiency of the solar cell produced are ongoing.

The efficiency of a solar cell may be enhanced by use of a passivation layer or an anti-reflective coating (ARC) layer over an emitter region in a silicon substrate that forms the solar cell. When light passes from one medium to another, for example from air to glass, or from glass to silicon, some of the light may reflect off from the interface between the two medium. The fraction of light reflected is a function of the difference in refractive index between the two mediums, wherein a greater difference in refractive indices of two adjacent medium results in a higher fraction of light being reflected from the interface therebetween.

The efficiency at which a solar cell converts incident light energy into electrical energy is adversely affected by a number of factors, including the fraction of incident light that is reflected off of a solar cell and absorbed in the cell structure, such as an anti-reflective coating (ARC) layer, and the recombination rate of electrons and holes in the solar cell. Each time an electron-hole pair recombines, charge carriers are eliminated, thereby reducing the efficiency of the solar cell. Recombination may occur in the bulk silicon of a substrate, which is a function of the number of defects in the bulk silicon, or on the surface of a substrate, which is a function of how many dangling bonds, i.e., unterminated chemical bonds, are present.

An anti-reflective coating (ARC) layer greatly improves the efficiency of the solar cell by reducing recombination rates, yet, the refractive index (n(λ)) needs to be tuned with the surrounding layers to minimize light reflection while also maintaining desired light absorption capabilities of the solar cell. Typically, a thin transparent film has an inherent extinction coefficient (k(λ)), the magnitude of which is an indication of the amount of light absorbed by the film, and an index of refraction (n), the magnitude of which is indicative of the degree to which the light bends when passing from one medium into another. The particular values of refractive index (n(λ)) and extinction coefficient (k(λ)) that are given are evaluated at a wavelength lambda (λ) which may differ for the measurement of refractive index (n(λ)) and extinction coefficient (k(λ)). A common lambda used to evaluate refractive index is at 633 nm wavelength, which is convenience for solar cells as this wavelength is close to the energy-weighted center point of the useful solar spectrum. A common lambda used to evaluate extinction coefficient is at 400 nm wavelength, which is convenience for ARC films as this wavelength is where considerable light absorption may occur in some types of the ARC films. Another method of expressing the concept of absorption in a dielectric material is to use the optical bandgap (E0 or Tauc gap), given in electron volts (eV). This concept is similar to extinction coefficient (k) is the sense that it is related to absorption. However, it differs in that the value E0 that describes the characteristic absorption of a larger range of wavelengths is often at the most of the useful solar spectrum. The value of E0 in eV describes roughly the value of photon energy where the onset of high absorption starts. For example, an E0 value of 3.0 eV would indicate a mostly transparent film at light energies below 3.0 eV and an increasingly absorbing film at light energies in excess of 3.0 eV.

In films such as SiN which are useful for an anti-reflective coating (ARC) layer, the magnitude of the n and k values are linked by the Kramers-Kronig relationship, in that if one is high, the other is likewise high. Because the range of the index of refraction of the anti-reflective coating (ARC) layer is limited by the materials, the range of resulting k values is also thus limited within the practice of the prior art, and thus an unacceptably high k value is seen as an unavoidable consequence of an acceptable index of refraction.

Therefore, there is a need for an improved method of forming a anti-reflective coating (ARC) layer or a passivation that has combined functional and optical gradient properties which minimize surface recombination of the charge carriers, improve the formed solar cell efficiency, and has desirable optical and passivating properties.

### SUMMARY OF THE INVENTION

In light of the above, embodiments of the present invention generally provide methods for fabricating an anti-reflective coating (ARC) layer that may act as both a high-quality passivation and ARC layer for solar cells. In one embodiment, a method of forming an anti-reflection layer on a solar cell substrate, the method includes flowing a first processing gas mixture into a processing chamber, wherein the first processing gas mixture includes at least a silicon containing gas and a nitrogen containing gas, wherein a ratio by flow volume of the silicon containing gas to the nitrogen containing gas supplied to the first processing gas mixture is controlled at between about between about 2:1 to about 1:5, applying a source RF power to the processing chamber in the presence of the first processing gas mixture, controlling the process pressure under 100 mTorr, and forming a silicon nitride containing layer on the substrate.

In another embodiment, a passivation/ARC layer formed in a solar cell device includes a dielectric layer disposed over one or more p-type doped regions formed in a surface of a solar cell, wherein the dielectric layer has a refractive index at 633 nm wavelength (n633) between about 2.0 and about 2.8 and an extinction coefficient at 400 nm wavelength (k400) less than 0.1, wherein the dielectric is a SiN, SiC or carbon layer.

In yet another embodiment, a solar cell device includes a substrate having a junction region passivation anti-reflection layer formed on a sun-facing surface of the substrate, the passivation anti-reflection layer including a dielectric layer disposed over one or more p-type doped regions formed in a surface of a solar cell, wherein the dielectric layer has a refractive index at 633 nm wavelength (n633) between about 2.0 and about 2.8 and an extinction coefficient at 400 nm wavelength (k400) less than 0.1, wherein the dielectric layer is a SiN, SiC or carbon layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts cross-sectional views of a portion of a crystalline solar cell substrate in accordance with one embodiment of the present invention;

FIG. 2A-2B are side cross-sectional views of an apparatus suitable for depositing an anti-reflective coating (ARC) layer according to one embodiment of the invention;

FIG. 3 depicts a process flow diagram of an anti-reflective coating (ARC) layer formation process performed on a solar cell substrate in accordance with one embodiment of the invention; and

FIGS. 4A-4C depict cross-sectional views of a portion of a crystalline solar cell substrate corresponding to various stages of the process illustrated in FIG. 3.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present invention generally provides methods of forming a high quality anti-reflective coating (ARC) layer with desired values of refraction index (n) and extinction coefficient (k) suitable to form a high efficiency solar cell device. In one embodiment, methods of forming a passivation/ARC layer with a high refractive index (n) but with a low extinction coefficient (k) are provided. By specific tailoring of the ratio by flow volume of different process chemistries supplied during film formation, the resultant ARC/passivation layer having specific properties of desired optical and functional properties may be obtained.

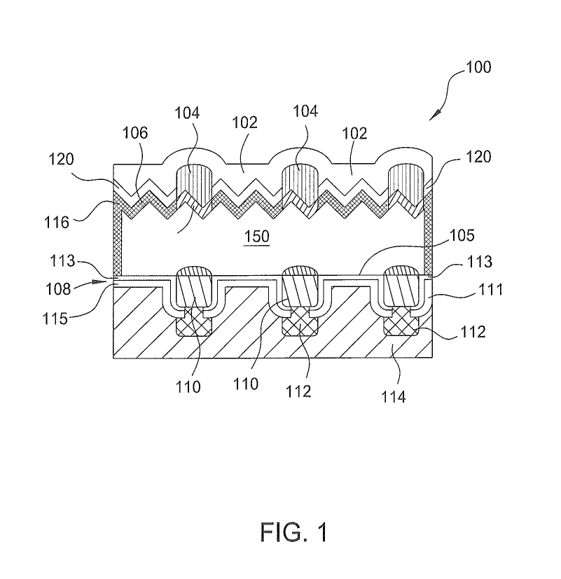

FIG. 1 depicts a cross-sectional view of a portion of a crystalline solar cell substrate 150 in accordance with one embodiment of the present invention. The substrate 150 has dopants disposed in one or more surfaces of the substrate 150. The substrate 150 may be a single crystal or multicrystalline silicon substrate, silicon containing substrate, doped silicon containing substrate, or other suitable substrates. In one embodiment, the substrate 150 is a doped silicon containing substrate with either p-type dopants or n-type dopants disposed therein. In one configuration, the substrate 150 is a p-type crystalline silicon (c-Si) substrate. P-type dopants used in silicon solar cell manufacturing are chemical elements, such as, boron (B), aluminum (Al) or gallium (Ga). In another configuration, the crystalline silicon substrate 150 may be an electronic grade silicon substrate or a low lifetime, defect-rich silicon substrate, for example, an upgraded metallurgical grade (UMG) crystalline silicon substrate. The upgraded metallurgical grade (UMG) silicon is a relatively clean polysilicon raw material having a low concentration of heavy metals and other harmful impurities, for example in the parts per million range, but which may contain a high concentration of boron or phosphorus, depending on the source. In certain applications, the substrate can be a back-contact silicon substrate prepared by emitter wrap through (EWT), metallization wrap around (MWA), or metallization wrap through (MWT) approaches. Although the embodiment depicted herein and relevant discussion thereof primarily discusses the use of a p-type c-Si substrate, this configuration is not intended to be limiting as to the scope of the invention, since an n-type c-Si substrate may also be used without deviating from the basic scope of the embodiments of the invention described herein. The doping layers or emitters formed over the substrate will vary based on the type of substrate as needed.

Optionally, a cleaning process is performed to clean the substrate 150 to form a textured surface 106. The cleaning process cleans surfaces of the substrate 150 to remove any undesirable materials and roughens the surface 106 of the substrate 150. The substrate 150 has the first surface 106 (e.g., a front surface) and a second surface 105 (e.g., a back surface), which is generally opposite to the first surface 106 and on the opposite side of the substrate 150. In one embodiment, the substrate 150 may be cleaned using any suitable techniques.

The textured surface 106 on the front side of the solar cell substrate 150 is adapted to receive sunlight after the solar cell has been formed. The textured surface 106 is formed to enhance light trapping in the solar cells to improve conversion efficiency. A dopant material, such as a doping gas, is used to form a doped region 116 (e.g., p⁺ or n⁺ doped region) on the surface 106 of the solar cell substrate 150. In one embodiment, the doped region 116 is formed in the substrate 150 by use of a gas phase doping process. In one embodiment, the doped region 116 is between about 50 Å and about 20 μm thick and comprises an n-type or p-type dopant atoms. In one embodiment, the doped region 116 may include n-type dopants that are disposed in a p-type substrate 150.

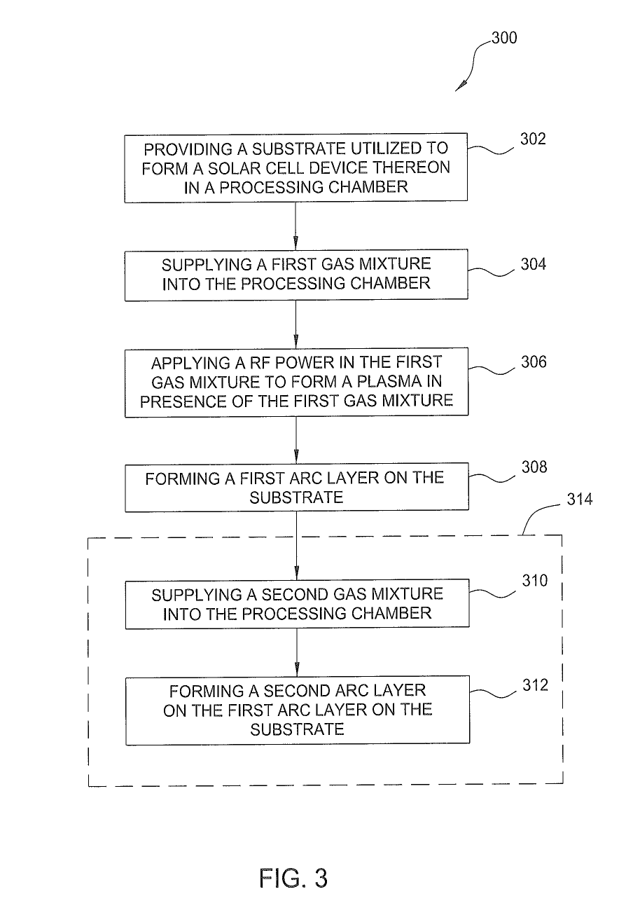

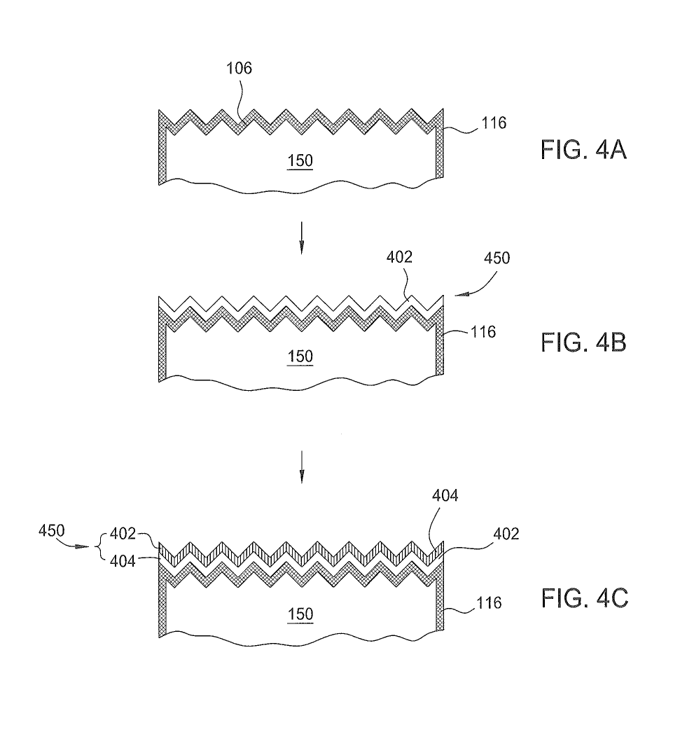

An antireflection coating (ARC) layer or passivation layer 120 is formed on the front textured surface 106 of the substrate 150. The ARC layer 120 may be manufactured by the process described below with referenced to FIGS. 3-4C. The ARC layer/passivation layer 120 may be in form of a single layer, dual layer, multiple layers, composite layers or the like. In one example, the antireflection layer/passivation layer 120 may be a thin ARC/passivation layer, such as silicon nitride, silicon oxynitride, or silicon oxide, which will be described later in detail with reference to FIGS. 3-4C. In one embodiment, the passivation/ARC layer 120 may be a single layer, a film stack comprising a first layer that is in contact with the front textured surface 116 and a second layer that is disposed on the first layer. A first metal paste 110 is selectively deposited on the back surface 105 to form back metal contacts by use of an ink jet printing, rubber stamping, stencil printing, screen printing, or other similar process to form and define a desired pattern where electrical contacts to the underlying substrate surface (e.g., silicon) are formed. In one embodiment, the first metal paste 110 is disposed in a desirable pattern on the substrate 150 by a screen printing process in which the back contact metal paste 110 is printed on the substrate 150 through a stainless steel screen. In one example, the screen printing process may be performed in a SoftLine™ system available from Applied Materials Italia S.r.l., which is a division of Applied Materials Inc., located Santa Clara, Calif. It is also contemplated that deposition equipment from other manufactures may also be utilized. In one embodiment, the first metal paste 110 may be selected from silver, silver alloy, copper (Cu), tin (Sn), cobalt (Co), rhenium (Rh), nickel (Ni), zinc (Zn), lead (Pb), and/or aluminum (Al), or other suitable metals to provide a proper conductive source for forming electrical contacts to the substrate surface.

A back side passivation layer 108 is deposited on the second surface 105 (e.g., back surface) of the substrate 150. The back side passivation layer 108 may be fabricated from a material similar to the material selected to manufacture the antireflection coating (ARC) layer/passivation layer 120 disposed on the front side 106 of the substrate 150. The back side passivation layer 108 may be a dielectric layer providing good surface/interface properties that reduce the recombination of the electrons and holes, drives and/or diffuses electrons and charge carriers. In one embodiment, the back side passivation layer 108 may be fabricated from a dielectric material selected from a group consisting of silicon nitride (Si₃N₄), silicon nitride hydride (SiₓN_{y}:H), silicon oxide, silicon oxynitride, a composite film of silicon oxide and silicon nitride, an aluminum oxide layer, a tantalum oxide layer, a titanium oxide layer, or any other suitable materials. In one embodiment, the passivation layer 108 comprises two layers or regions, such as an aluminum oxide layer (AlₓO_{y}) 113 disposed on the back surface 105 of the substrate 150 and a silicon nitride layer 111 disposed on the aluminum oxide layer (AlₓO_{y}) 113.

Metallization layers, including front contact structures 104 and/or a conductive bus-line 102, are formed on the ARC/passivation layer 120 on the front surface of the substrate 150. The front contact structures 104 may be deposited in a desirable pattern on the surface of the ARC/passivation layer 120 after the back contact metal paste 110 is disposed on the back surface 105 of the substrate 150. In general, the front contact structures 104 may be between about 500 angstroms and about 100,000 angstroms (λ) thick, about 10 μm to about 200 μm wide, and contain a metal, such as aluminum (Al), silver (Ag), tin (Sn), cobalt (Co), rhenium (Rh), nickel (Ni), zinc (Zn), lead (Pb), palladium (Pd), molybdenum (Mo), titanium (Ti), vanadium (V), tungsten (W), or chromium (Cr). In one example, the front conductive contact 104 is a metallic paste that contains silver (Ag) and is deposited in a desired pattern by a screen printing process. The screen printing process may be performed by a SoftLine™ system available from Applied Materials Italia S.r.l.

The conductive bus-line 102 is formed and attached to at least a portion of the front contact structures 104 to allow the solar cell device to be connected to other solar cells or external devices. In one embodiment, the conductive bus-line 104 is connected to the front contact structures 104 using a soldering material that may contain a solder material (e.g., Sn/Pb, Sn/Ag) if necessary. In one embodiment, the conductive bus-line 102 is about 200 microns thick and contains a metal, such as aluminum (Al), copper (Cu), silver (Ag), gold (Au), tin (Sn), cobalt (Co), rhenium (Rh), nickel (Ni), zinc (Zn), lead (Pb), palladium (Pd), and/or aluminum (Al). In one embodiment, each of the conductive bus-lines 104 are formed from a wire that is about 30 gauge (AWG: ˜0.254 mm) or smaller in size. In one embodiment, the conductive bus-line 102 is coated with a solder material, such as a Sn/Pb or Sn/Ag solder material.

A second metal paste 112 and a conductive layer 114 may be formed on the back side passivation layer 108 on the back surface 105 of the substrate 150. The second metal paste 112 may be formed, disposed, and/or deposited over the underlying first metal paste 110 so that conductive paths may extend from the back surface 105 of the substrate 150 to a portion of the second metal paste 112 during a subsequent thermal processing step. In one embodiment, the second metal paste 112 may be formed from similar materials and similar process described above with reference to the process described to form the first metal paste 110.

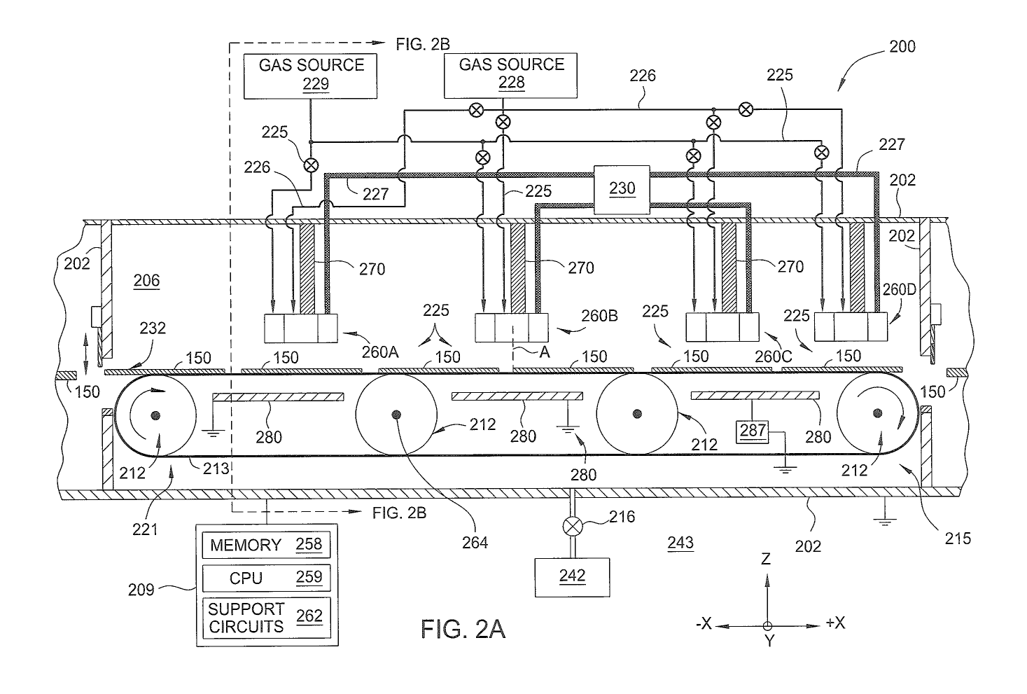

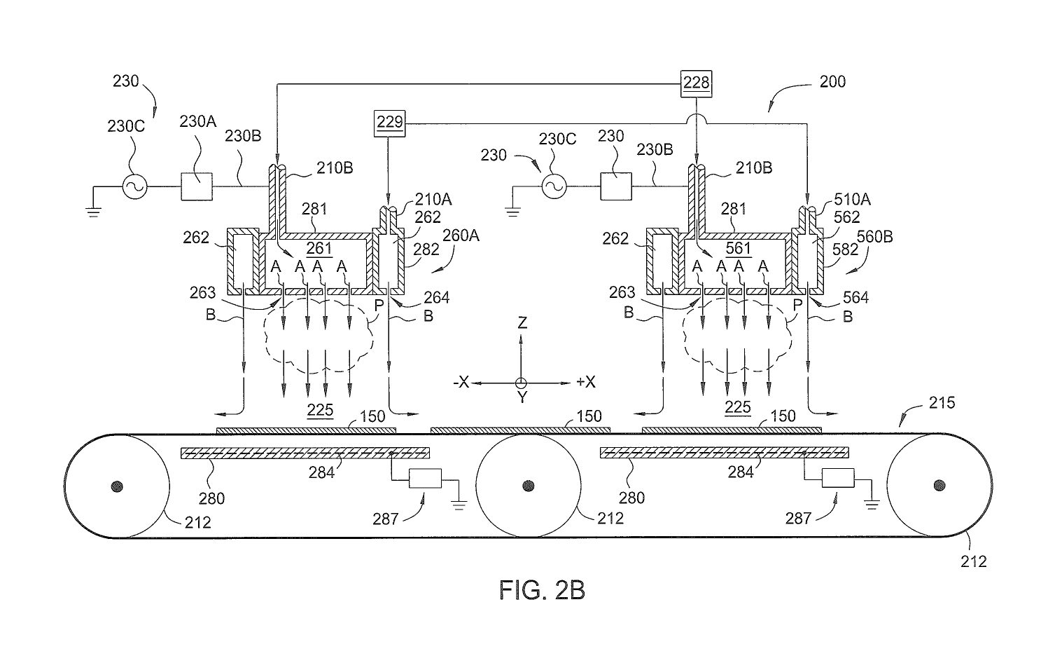

FIGS. 2A-2B are side cross-sectional views of one embodiment of a processing chamber 200 in which a ARC/passivation layer deposition process, such as for depositing the back side passivation layer 108 or the antireflection coating (ARC) layer or passivation layer 120, may be performed in accordance with one embodiment of the invention. FIG. 2A is a side cross-sectional view of the processing chamber 200 that is positioned in a cluster processing system (not shown) that may receive a linear array of substrates to be processed under different types of processing chambers incorporated in the cluster processing system as needed. The processing chamber 200 may be aligned relative to a transfer direction, or parallel to a X-direction of the cluster processing system. One suitable processing chamber and the cluster processing system described herein may be practiced in a Terracotta® system available from Applied Materials, Inc., located in Santa Clara, Calif. It is contemplated that other deposition chambers and the cluster processing system including those from other manufacturers may be utilized to practice the present invention.

In one embodiment, the processing chamber 200 comprises one or more deposition sources, such as deposition sources 260A-260D shown in FIG. 2A, gas sources 228 and 229, a power source 230, chamber walls 202 that at least partially enclose a portion of the processing region 206, and at least a portion of the substrate automation system 215. FIG. 2B is a close-up side cross-sectional view of two deposition sources 260A and 260B that are intended to form a passivation layer on the surface of the substrates 150 as they pass under the deposition sources. The walls 202 generally comprise a material that can structurally support the loads applied by the environment 243, which is external to the processing region 206, when it is heated to a desirable temperature and pumped to a vacuum pressure by a vacuum pump 242. The walls 202 comprise a material such as an aluminum material or stainless steel.

In one configuration, the portion of the substrate automation system 215 comprises an intermediate conveyor 221 that is adapted to support, guide move the substrates 200 through the processing chamber by use of one or more actuators (not shown), for example, a stepper motor or servo motor. In one configuration, the intermediate conveyor 221 comprises a two or more rollers 212 and a belt 213 that are configured to support and move the rows of substrates 150 in a positive +X-direction during processing (as shown in FIG. 2B).

In one embodiment of the processing chamber 200, each of the deposition sources 260A-260D are coupled to at least one gas source, such as a central gas source 228 and an edge gas source 229, that is configured to deliver one or more processing gases to a processing region 225 formed with the processing region 206, and below each of the deposition sources and over the surface of a substrate 150 disposed there under. As illustrated in FIG. 2B, the deposition sources 260A-260D are configured to extend over the substrates 150 disposed on the substrate automation system 215.

As illustrated in FIG. 2B, the deposition sources comprise at least one gas delivery element, such as a first gas delivery element 281 and second gas delivery element 282, which are each configured to direct the processing gases to the processing region 225. The first gas delivery element 281 comprises a fluid plenum 261 that is configured to receive the process gas from the central gas source 228 and deliver the received gas to the processing region 225 through a plurality of holes 263 formed therein. Similarly, the second gas delivery element 282 comprises a fluid plenum 262 that is configured to receive the process gas from the edge gas source 229 and deliver the received gas to the processing region 225 through a plurality of holes 264 formed therein. The gas sources 228 and 229 are configured to provide one or more precursor gases and/or carrier gases that are used to deposit a layer on the surface of the substrates 150 by use of a PECVD process. In one process sequence, at least one of the gas sources 228 and 229 is configured to deliver a silicon containing gas to a deposition source, such as silane (SiH₄), and at least one of the gas sources 228 and 229 is configured to a nitrogen containing gas, such as nitrogen (N₂) or ammonia (NH₃) so as to form a silicon nitride layer on the surface of the substrates. In another embodiment, at least one of the gas sources 228 and 229 is configured to deliver a silicon containing gas to a deposition source, such as silane (SiH₄) and a carbon containing gas, such as methane (CH₄), to form a silicon carbide layer (SiₓC_{y}H_{z}) on the surface of the substrate. In another embodiment, at least one of the gas sources 228 and 229 is configured to deliver a carbon containing gas to a deposition source, such as methane (CH₄), acetylene (C₂H₂), ethylene (C₂H₄), carbon tetrachloride (CCl₄), chloroform (CHCl₃), dichloromethane (CH₂Cl₂), or chloromethane (CHCl₃), and a hydrogen containing gas, such as hydrogen (H₂), to form a diamond carbon layer (CₓH_{y}) on the surface of the substrate. In another embodiment, at least one of the gas sources 228 and 229 is configured to deliver an aluminum containing gas to a deposition source, such as trimethylaluminum (TMA), and an oxygen containing gas, such as oxygen (O₂), or nitrous oxide (N₂O), to form an aluminum oxide layer (AlₓO_{y}) on the surface of the substrates. In another embodiment, at least one of the gas sources 228 and 229 is configured to deliver an aluminum containing gas to a deposition source, such as trimethylaluminum (TMA), and a nitrogen containing gas, such as oxygen (N₂), nitrous oxide (N₂O) or ammonia (NH₃) and an oxygen containing gas, such as oxygen (O₂) or nitrous oxide (N₂O), to form an aluminum oxynitride layer (AlₓO_{y}N_{z}) on the surface of the substrates.

In one configuration, as shown in FIG. 2B, the power source 230 is configured to deliver RF energy to the processing region 225 by use of an RF power supply 230C, an optional match 230A (e.g., matching network) and electrical connection 230B to form a plasma “P” within the processing region 225 to enhance the deposition process being performed on the substrates 150. In one embodiment, an electrical bias is applied an electrode 280 disposed within the processing region 206 to help improve the properties of the deposited film. In one configuration, a bias is applied to the electrode 280 by use of an electrical source 287 (FIG. 2A) that may comprise an active electrical biasing source (e.g., AC or DC power supply) or switch that selectively grounds portions of the electrode 280. In one embodiment, the electrode 280 may include a heating element 284, such as resistive heating element 284 that may be powered by a separate heater power supply (not shown). The electrode 280 is positioned proximal to the substrates 150 in order to heat the substrate 150 to a temperature of about 200° C. to about 550° C. during processing. The electrode 280 and/or heating element 284 may be fabricated from an electrically conductive material to function as a ground or radio frequency (RF) electrode to act as an electrode in a capacitively coupled plasma.

During process, a first precursor gas is flowed to the processing region 225 at a first rate and a second precursor gas is flowed at a second rate so as to provide different plasma density and/or different ion flux in the plasma volume 225 to form a film having adjustable and differing composition. A graded film may be formed by using the same or different precursors. In one embodiment, the graded film may be one or more layers of hydrogenated silicon nitride (Si_{X}N_{Y}:H) having different concentrations of hydrogen and/or Si:N bonds throughout. In another embodiment, one or more of the layers of the graded film may be aluminum oxide (Al_{X}O_{Y}) or aluminum oxynitride (Al_{X}O_{Y}N_{Z}) having different stoichiometry, such as differing ratios of aluminum to oxygen. While a slight temporal separation will be encountered by the material layers formed on the substrate 150, a single continuous film may be formed on the surface of the substrate 150. In one example, a first flow rate of precursor gases from the first gas source 228 and a second flow rate of precursor gases from the second gas source 229.

FIG. 3 is a flow diagram of one embodiment of a process 300 for fabricating an ARC/passivation layer, such as the ARC/passivation layer 120 or the back side passivation layer 108 depicted in FIG. 1, according to one embodiment of the present invention. The process 300 may be performed in a processing chamber, such as the processing chamber 200 depicted in FIG. 2A-2B or other suitable chamber. FIGS. 4A-4C depict a sequence of fabrication stages of performing the ARC/passivation layer deposition process on a substrate according to the process 300 depicted in FIG. 3.

The process 300 starts at step 302 by transferring a substrate, such as the substrate 150, as shown in FIG. 4A, to a processing chamber, such as the processing chamber 200 depicted in FIGS. 2A-2B or other suitable chamber. In the embodiment depicted in FIG. 4A, the substrate 150 is similarly constructed to the embodiment depicted in FIG. 1. The substrate 150 includes the textured surface 106 having the doped region 116 formed thereon. The structures/features formed on the back side of the substrate 150 is not shown and eliminated for sake of brevity.

At step 304, a first gas mixture is supplied into the processing chamber. In one example, the gas mixture may include at least a silicon containing gas and a nitrogen containing gas to form a silicon nitride containing layer as the ARC/passivation layer 450 on the substrate 150, as shown in FIG. 4B. In the embodiment depicted in FIG. 4B, a single layer of ARC/passivation layer 402 is used. Suitable examples of the silicon containing gas include SiH₄, Si₂H₆, SiCI₄ and the like. Suitable examples of the nitrogen containing gas include N₂, NH₃, N₂O, NO₂, combinations thereof and the like. In one embodiment described herein, the silicon containing gas supplied in the first gas mixture is SiH₄ and the nitrogen containing gas supplied in the first gas mixture is N₂. The sequence of the deposited layers is chose to most advantageously provide a good surface or interface passivation and optical gradient for the given solar cell wafer and junction type.

The ARC/passivation layer 402 is configured to have desirable optical properties to minimize light reflection and absorption as light passes through the ARC/passivation layer 402. Balancing the desired properties of the ARC/passivation layer 402 for a solar cell is challenging. In the embodiment depicted herein with referenced to FIG. 4B, the ARC/passivation layer 402 is configured to be a silicon nitride layer. The challenge increases when using silicon nitride (SiₓN_{y}, also abbreviated SiN) films as the ARC/passivation layer 402 because achieving desired film properties requires balancing competing process parameters for forming the ARC/passivation layer 402 having particular optical or functional qualities. It is even difficult to obtain low extinction coefficient (k) properties in the silicon nitride along with a high refractive index (n). Often times, in practice, having a film with a high index of refraction (n) also means generating a film having a high extinction coefficient (k) when using conventional film formation methods. In other words, the variables n and k mirror each other where n and k generally go up or down together when forming a film according to conventional methods. Independence between the magnitude of k and n values would provide the ability to combine the desired optical and functional properties into an ARC/passivation layer, i.e. to enable a lower k, and thus less light loss, and at the same time a higher n, and thus lower reflectance. It should be noted that the measured values of n and k are dependent on frequency i.e. the wavelength of light, at which they are measured. The k and n values discussed herein are measured at 400 nm and 633 nm wavelengths respectively.

In one embodiment, it is found that silicon-silicon bonding (Si—Si) has significant influence on the magnitude of k value. In the case higher ratio of the silicon-silicon bonding (Si—Si) is found in the resultant ARC/passivation layer, the higher value of k is also obtained. Accordingly, by efficiently controlling the bonding structures of the resultant ARC/passivation layer 402, a desired balance of the values of n and k may be obtained. As discussed above, the N—H/Si—H bond ratio may be important to tailor the optical properties of the ARC/passivation layer 402. By increasing the power of the plasma, lowering the process pressure along with a specific ratio by flow volume of the silicon containing gas and the nitrogen containing gas supplied in the first gas mixture during the deposition of ARC/passivation layer 402, it is believed that the resulting deposited film will have an increased refractive index (n) and lowered k value compared to a conventionally deposited passivation layer deposited. In most of the cases, at least two types of bonds found in a silicon solar cell having a silicon-nitride type passivation layer that cause absorption of light are Si—H bonds and Si—Si bonds. Si—H and Si—Si bonds, however, are not a part of a silicon nitride material, which is theoretically all Si₃N₄, sometimes referred to as stoichiometric silicon nitride. However, a stoichiometric silicon nitride film of only Si₃N₄ would be a poor solar ARC material because there would be no hydrogen therein, which would result in poor overall solar cell efficiencies as the refractive index of stoichiometric silicon nitride is around 1.9. Thus, hydrogen needs to be added to a silicon nitride ARC layer to further enhance its antireflective and passivating properties.

When hydrogen is added to a silicon nitride film on a silicon substrate, some of the hydrogen goes to form N—H bonds and Si—H bonds. Si—H material absorbs light at the edge of the UV range and contributes a minor portion to the total k values whereas the Si—Si material absorbs visible light and thus contributes the major portion to the total k value. Extra silicon is needed in order to get the refractive index to the desired levels for the solar cell. The extra silicon, however, does not have to be bonded to other silicon atoms. It is believed that using a high plasma power during the deposition of the passivation layer(s) inhibits the formation of Si—Si bonds (though not necessarily completely prevents) and enhances the formation of Si—N and/or Si—H bonds in the growing film. In other words, a high plasma power density, low process pressure along with a specific ratio by flow volume of the silicon containing gas and the nitrogen containing gas minimize bonding of Si atoms in the growing film, and/or initially at the substrate surface, from bonding with Si atoms found in the silicon-containing precursor gas. By minimizing the Si—Si bonding and increasing the percentage of Si—N and Si—H bonds in the growing film, the k value of the deposited silicon nitride film can be adjusted and/or controlled.

In one embodiment, a specific gas ratio range by flow volume of silicon containing gas and the nitrogen containing gas is regulated during deposition so as to create the ARC/passivation layer 402 with specific bonding structures with desired ratio among different elements, such as silicon, nitrogen and hydrogen (Si:N:H). In one example, it is desired to have a relatively higher silicon hydrogen bonding (Si—H), silicon nitrogen bonding (SiN) rather than silicon-silicon bonding (Si—Si). By doing so, comparatively, a low value of k is obtained since the low ratio of the silicon-silicon bonding (Si—Si) is controlled in the resultant ARC/passivation layer 402.

In one embodiment, the ratio of the silicon element contained in the resultant ARC/passivation layer 402 is controlled between about 50 percent by volume and about 75 percent by volume, such as between about 60 percent by volume and about 65 percent by volume. The ratio of the hydrogen element contained in the resultant ARC/passivation layer 402 is controlled between about 10 percent by volume and about 25 percent by volume. The ratio of the nitrogen element contained in the resultant ARC/passivation layer 402 is controlled between about 10 percent by volume and about 25 percent by volume.

The silicon containing gas supplied in the total first gas mixture is at a ratio by flow volume controlled at between about 20 percent by volume and 70 percent by volume. The nitrogen containing gas supplied in the total first gas mixture is at a ratio controlled at between about 60 percent by volume and 80 percent by volume. Alternatively, the silicon containing gas and the nitrogen containing gas supplied in the first gas mixture is controlled at a ratio by flow volume between about 2:1 to about 1:5, such as between about 1.5:1 and about 1:1. In one embodiment, the silicon containing gas is supplied between about 550 sccm and about 750 sccm. The nitrogen containing gas is supplied between about 400 sccm and about 800 sccm.

In one embodiment, the silicon containing gas may be selected to be supplied to the processing region 225 through the central gas source 228 and the nitrogen containing gas maybe selected be supplied to the processing region 225 through the edge gas source 229. This allows for the silicon containing gas to be ionized or reacted indirectly by the activated nitrogen containing gas, preventing deposition or buildup of silicon-containing residuals inside the plasma source.

At step 306, a source RF power is applied to the processing chamber to form a plasma in the presence of the first gas mixture supplied at step 304. It is found that by using a higher power for depositing the resultant ARC/passivation layer 402, k and n tend to be more independent than when using normal (i.e., lower) power ranges. Relatively high plasma power density permits formation of desired film properties exhibiting both optical and functional gradient properties that are not a compromise based on traditional couplings of high k values to high n values and low k values with low n values, and yet, by using a multi-layer deposition for forming the passivating layer, pinholes extending through the entire film layer are avoided. In one embodiment, the RF power is controlled to be over 3000 Watts over a linear source that is 400 mm wide, or alternatively over 100 Watts per linear cm, such as between about 75 Watts/cm and about 150 Watts/cm, for example about 92 Watts/cm.

Additionally, by utilizing a relatively power pressure range, such as less than 100 mTorr, a lower k value may also be obtained. It is believed that the lower pressure range controlled during deposition may assist dividing the silicon-silicon bonding (Si—Si) and prevention formation of the silicon-silicon cluster structures, thereby efficiently reducing the k value formed in the resultant ARC/passivation layer 402. Furthermore, the optical bandgap of the ARC/passivation layer 402 can also be controlled above 3.0 eV. In one embodiment, the pressure is controlled at less than 100 mTorr, such as about less than 20 mTorr, for example about 6 mTorr.

Several process parameters may be controlled while performing the buffer layer deposition process. A bias power less than about 1000 Watts may be used to assist controlling direction of the ions generated in the plasma in presence of the first gas mixture. The substrate temperature may be controlled between about 150 degrees Celsius and about 500 degrees Celsius, such as about 385 degrees Celsius. The spacing may be controlled between about 800 mils and about 2000 mils, such as 1000 mils. The process time may be controlled at a range when a desired thickness of the ARC/passivation layer 402 is reached, such as between about 300 Å and about 600 Å, such as about 500 Å. Suitable process time may be controlled between about 4 seconds and about 24 seconds.

At step 308, the ARC/passivation layer 402 is formed on the substrate 150, as shown in FIG. 4B. Under the above described process parameters, a refractive index (n633) of the ARC/passivation layer 402 between about 2 and about 2.8, for example between about 2.0 and about 2.5, such as about 2.2, at 633 nm wavelength is obtained. An extinction coefficient (k400) of the ARC/passivation layer 402, less than 0.1, such as about 0.05 or approximately to 0, at 400 nm wavelength is also obtained.

In another embodiment, different materials may also be utilized to form the ARC/passivation layer 402. In one embodiment, a silicon carbide layer (SiₓC_{y}H_{z}) may also be used to form the ARC/passivation layer 402. In this embodiment, the precursor used to form the SiC layer may be a silicon containing gas, such as the silicon containing layer supplied in the first gas mixture at step 304, and a carbon containing gas. In another embodiment, the process may use only the carbon containing gas without the silicon containing gas, forming a diamondoid carbon (CₓH_{y}) layer. Suitable examples of the carbon containing gas may be a hydrocarbon gas, such as CH₄, C₂H₆, C₂H₄ or any other suitable carbon containing gas. In some embodiment, a hydrogen gas (H₂) diluent may be supplied along with the carbon containing gas as needed to form the ARC/passivation layer 402. In one embodiment, the refractive index (n) of the carbon containing ARC/passivation layer 402 is controlled between about 2.0 and about 2.8 at 633 nm wavelength, such as between about 2.2 and about 2.6, for example about 2.4. The optical bandgap is controlled greater than 3.0 eV. Alternatively, TiO₂ material, ZnS, or ZnSe may also be used having a desired range of refractive index (n), such as between about 2.0 and about 2.8, as needed.

Additionally, optional steps of step 310 and 312, as indicated by the dotted line 314, may be selectively performed to form a capping ARC/passivation layer 404 on the ARC/passivation layer 402, as shown in FIG. 4C. The capping ARC/passivation layer 404 along with the ARC/passivation layer 402 in combination forms a dual film structure, e.g., a composite film stack, as an ARC/passivation layer with desired optical, passivate and functional properties.

At step 310, a second gas mixture is supplied in the processing chamber to deposit a capping ARC/passivation layer 404 on the underlying ARC/passivation layer 402, as shown in FIG. 4C. In one embodiment, the second gas mixture may include at least a silicon containing gas, oxygen containing gas and/or a nitrogen containing gas. Suitable examples of the silicon containing gas include SiH₄, Si₂H₆, SiCI₄ and the like. Suitable examples of the oxygen containing gas include O₂, O₃, N₂O, NO₂, NO, H₂O, H₂O₂, combinations thereof and the like. Suitable examples of the nitrogen containing gas include N₂, NH₃, N₂O, NO₂, combinations thereof and the like. In one embodiment described herein, the silicon containing gas supplied in the second gas mixture is SiH₄ and the nitrogen containing gas supplied in the second gas mixture is N₂. Alternatively, a metallic precursor may also be used to form metal containing dielectric material as the capping ARC/passivation layer 404 on the substrate 150 as needed. In one embodiment, the metallic precursor may include aluminum containing complex, such as diethylalumium ethoxide (Et₂AlOEt), triethyl-tri-sec-butoxy dialumium (Et₃Al₂OBu₃, or EBDA), trimethyldialumium ethoxide, dimethyl aluminum isupropoxide, disecbutoxy aluminum ethoxide, (OR)₂AIR′, wherein R and R′ may be methyl, ethyl, propyl, isopropyl, butyl, isobutyl, tertiary butyl, and other alkyl groups having higher numbers of carbon atoms, and the like, as needed.

At step 312, after the second gas mixture is supplied in the processing chamber, process parameters may be regulated during deposition to form the capping ARC/passivation layer 404 on the underlying ARC/passivation layer 402. In one embodiment, the capping ARC/passivation layer 404 may be a silicon oxynitride (SiON) layer, a silicon oxide layer, such as PECVD oxide, thermal oxide, or any other suitable oxide layer, or other suitable dielectric materials. In another embodiment, aluminum oxide (Al₂O₃), aluminum oxynitride (AlON) may also be utilized to form the capping ARC/passivation layer 404 with desired film properties. The capping ARC/passivation layer 404 is controlled to have a refractive index (n) greater than the refractive index (n) of the ARC/passivation layer 402 disposed underneath. In one embodiment, the capping ARC/passivation layer 404 may be controlled to have a refractive index (n) between about 1.0 and about 2.0 at 633 nm wavelength. In the embodiment wherein a SiON, SiN or SiO₂ is utilized as the capping ARC/passivation layer 404, the refractive index (n) is controlled between about 1.0 and about 1.8, such as about 1.7, at 633 nm wavelength. In the embodiment wherein a Al₂O₃ or a AlON layer is used as the capping ARC/passivation layer 404, the refractive index (n) is controlled between about 1.5-2.0, such as between about 1.6 and about 1.7, at 633 nm wavelength. In one embodiment, the capping ARC/passivation layer 404 is controlled to have a thickness range between about 300 Å and about 600 Å, such as about 500 Å.

The discussion above primarily discloses a method for fabricating an ARC/passivation layer with desired range of refractive index and extinction coefficient. In one embodiment, a single layer of a silicon nitride containing layer having a high range of refractive index and low range of extinction coefficient is used. In another embodiment, a dual layer of a silicon nitride containing layer along with a silicon oxide containing layer or other suitable layer disposed thereon may be utilized so as to provide desired optical, passivative and functional film properties to the crystalline solar cell devices.

While the foregoing is directed to embodiments of the present invention, other and further embodiments of the invention may be devised without departing from the basic scope thereof, and the scope thereof is determined by the claims that follow.

What is claimed is:

1. A method of forming an anti-reflection layer on a solar cell substrate, the method comprising:
flowing a first processing gas mixture into a processing chamber, wherein the first processing gas mixture includes at least a silicon containing gas and a nitrogen containing gas, wherein a ratio by flow volume of the silicon containing gas to the nitrogen containing gas supplied to the first processing gas mixture is controlled at between about between about 1:1 to about 1:5;
applying a source RF power to the processing chamber in the presence of the first processing gas mixture;
controlling the process pressure under 100 mTorr; and
forming a silicon nitride containing layer on the substrate.

2. The method of claim 1, further comprising:
forming a capping ARC layer on the silicon nitride containing layer on the substrate.

3. The method of claim 2, wherein the capping ARC layer is selected from a group consisting of SiO₂, SiON, Al₂O₃, and AlON.

4. The method of claim 1, wherein applying the RF source power further comprises:
applying the RF source power greater than 3000 Watts to the processing chamber in presence of the first processing gas mixture.

5. The method of claim 1, wherein applying the RF source power further comprises:
applying the RF bias power less than 1000 Watts to the processing chamber in presence of the first processing gas mixture.

6. The method of claim 1, wherein the silicon nitride containing layer formed on the substrate has a refractive index (n) between about 2 and about 2.8 at 633 nm wavelength.

7. The method of claim 1, wherein the silicon nitride containing layer formed on the substrate has an extinction coefficient (k value) less than 0.1 at 400 nm wavelength.

8. The method of claim 1, wherein the first process gas mixture comprises nitrogen and silane.

9. The method of claim 1, wherein applying the RF source power further comprises:
controlling a substrate temperature between about 150 degrees Celsius and about 500 degrees Celsius.

10. The method of claim 2, wherein the silicon nitride containing layer and the capping ARC layer are formed in the same processing chamber.

11. A passivation/ARC layer formed in a solar cell device, comprising:
a dielectric layer disposed over one or more p-type doped regions formed in a surface of a solar cell, wherein the dielectric layer has a refractive index at 633 nm wavelength (n633) between about 2.0 and about 2.8 and an extinction coefficient at 400 nm wavelength (k400) less than 0.1, wherein the dielectric is a SiN, SiC or carbon layer.

12. The passivation/ARC layer of claim 11, wherein the dielectric layer is a silicon nitride layer having a ratio of silicon elements contained in the silicon nitride layer between about 60 percent by volume and about 65 percent by volume.

13. The passivation/ARC layer of claim 11, wherein the dielectric layer is a silicon nitride layer having a ratio of hydrogen elements contained in the silicon nitride layer between about 10 percent by volume and about 25 percent by volume.

14. The passivation/ARC layer of claim 11, wherein the dielectric layer is a silicon nitride layer having a ratio of nitrogen elements contained in the silicon nitride layer between about 10 percent by volume and about 25 percent by volume

15. The passivation/ARC layer of claim 11, further comprising:
a capping ARC layer formed on the silicon containing layer.

16. The passivation/ARC layer of claim 15, wherein the capping ARC layer has a refractive index less than the refractive index of the silicon containing layer.

17. The passivation/ARC layer of claim 15, wherein the capping ARC layer has a refractive index (n) between about 1.0 and about 2.0.

18. A solar cell device, comprising:
a substrate having a junction region passivation anti-reflection layer formed on a sun-facing surface of the substrate, the passivation anti-reflection layer including a dielectric layer disposed over one or more p-type doped regions formed in a surface of a solar cell, wherein the dielectric layer has a refractive index at 633 nm wavelength (n633) between about 2.0 and about 2.8 and an extinction coefficient at 400 nm wavelength (k400) less than 0.1, wherein the dielectric layer is a SiN, SiC or carbon layer.

19. The solar cell device of claim 18, further comprising:
a capping ARC layer disposed on the passivation anti-reflection layer, wherein the capping ARC layer has a refractive index less than the refractive index of the passivation anti-reflection layer.

20. The solar cell device of claim 18, wherein the capping ARC layer has a refractive index (n) between about 1.0 and about 2.0.
